(19) United States
(12) Patent Application Publication
(10) Pub. No.: US 2002/0045353 A1
(43) Pub. Date: Apr. 18, 2002

(54) Method for manufacturing semiconductor device using octafluorobutene etching gas and semiconductor device manufactured thereby

(76) Inventor: Chang-jin Kang, Tokyo (JP)

Correspondence Address: The Law Offices of Eugene M Lee, PLLC, Suite 1200, 2111Wilson Boulevard, Arlington, VA, 22201, US

(21) Appl. No.: 09/865,585

(22) Filed: May 29, 2001

(30) Foreign Application Priority Data
Aug. 29, 2000 (KR) 00-50358

(51) Int. Cl. H01L 21/461; H01L 21/302

(52) U.S. Cl. 438/710; 438/706

(57) ABSTRACT

A method for manufacturing a semiconductor device placing a semiconductor substrate with a silicon oxide-containing layer thereon into a plasma reaction chamber, supplying an etching gas containing a linear octafluorobutene into the plasma reaction chamber, and etching at least a portion of the silicon oxide-containing layer by generating plasma from the etching gas.

### BACKGROUND OF THE INVENTION

1. Field of the Invention

The present invention relates to a method for manufacturing a highly integrated semiconductor device, and more particularly, to a semiconductor device manufacturing method involving etching a silicon oxide-containing layer by dry etching using plasma.

2. Description of the Related Art

With the increase in the integration density of semiconductor devices, the gap between a contact hole, which connects lower and upper interconnect layers each other, and adjacent interconnect structures, becomes narrower as the aspect ratio of the contact hole increases. In forming such a contact hole in a high integration density semiconductor device by lithography, accurate and restricted processing control is needed. However, the current lithography technique is limited to manufacturing a semiconductor device having a 0.25 μm design rule with reproducibility.

To cope with the limitation of the lithography process applied to form a contact hole, a method of forming a self-aligned contact hole has been suggested. As an example of this method, an oxide layer is etched using a nitride spacer as an etch barrier, so that a contact hole is formed. In particular, in the conventional self-aligned contact hole formation method using a nitride spacer as an etch barrier, first a predetermined lower structure having a substantially rectangular section, for example, including a conductive layer such as gate electrodes, is formed over a semiconductor substrate by patterning with application of a known photolithography process. Following this, a nitride layer is deposited over the semiconductor substrate with the lower structure, and etched back to form an etch barrier on the conductive layer. Then, an interlevel dielectric (ILD) film is deposited with an oxide layer over the semiconductor substrate. A photoresist pattern, through which a portion of the ILD film to be a contact hole region is exposed, is formed on the ILD film. Then, the exposed portion of the ILD film is etched using the photoresist pattern as an etch mask, thereby resulting in a self-aligned contact hole.

In etching the oxide layer into a self-aligned contact hole, a high etching selectivity with respect to the underlying layer, i.e., the nitride layer, is required. To meet this requirement, in the conventional self-aligned contact hole formation, an etching gas having a high etching selectivity is used in etching the oxide layer. The etching gas includes a gas mixture of an inert gas and a CxFy-based perfluorocarbon (PFC) gas, such as CF₄, C₂F₆, C₃F₆, C₃F₈, C₄F₆, c-C₄F₈, and C₅F₈. In addition, as an etching gas having high etching selectivity, a CₓH_{y}F_{z}-based hydrofluorocarbon (HFC), hydrofluoroether (HFE) or iodine fluorinated carbon (IFC) gas is used alone, or is used as an additive to the PFC gas.

However, almost all of these etching gases fail to satisfy the requirement for high oxygen-to-nitride selectivity, or the need for a desired etch rate. Due to the poor dry etching properties of the etching gases, practical use of the etching gases is difficult. As for c-C₄F₈, which is a PFC gas widely used as a source gas in dry etching an oxide layer in the conventional contact hole formation method, the global warming potential (GWP) of this gas is thousands of times larger than CO₂. Accordingly, if the c-C₄F₈ used is directly exhausted into the atmosphere, the environment can be adversely affected.

There is a need for a new alternative to the conventional etching gases, which can be used effectively in etching the oxide layer.

### SUMMARY OF THE INVENTION

It is a feature of the present invention to provide a method for manufacturing a semiconductor device in which a silicon oxide-containing layer is etched by plasma with excellent etching properties.

It is another feature of the present invention to provide a method for manufacturing a semiconductor device, in which the limitation of oxide-to-nitride etching selectivity in the etching process using a nitride layer as an etch barrier can be overcome.

It is still another feature of the present invention to provide a method for manufacturing a semiconductor device that essentially eliminates effects which contribute to the global warming problem.

In accordance with one aspect of the present invention, there is provided a method for manufacturing a semiconductor device, comprising: placing a semiconductor substrate with a silicon oxide-containing layer thereon into a plasma reaction chamber; supplying an etching gas containing a linear octafluorobutene into the plasma reaction chamber; and etching at least a portion of the silicon oxide-containing layer by generating plasma from the etching gas.

In particular embodiments, the linear octafluorobutene is octafluorobutene (CF₂=CFCF₂CF₃) or octafluoro-2-butene (CF₃CF=CFCF₃).

In additional particular embodiments, the etching gas further comprises a first gas having the formula CₓF_{y}, where x=1-5, and y=2-12, a second gas having the formula CₓH_{y}F_{z}, where x=1-5, y=1-4, and z=2-10, or a mixture of the first and second gases. The first gas can comprise at least one selected from the group consisting of CF₄, C₂F₆, C₃F₆, C₃F₈, C₄F₆, c-C₄F₈ (octafluorocyclobutane), and C₅F₈. The second gas can comprise at least one selected from the group consisting of CHF₃, CH₂F₂, and CH₃F. According to further particular embodiments, the etching gas can further comprise a rare (i.e., noble) gas.

In accordance with another aspect of the present invention, there is provided a method for manufacturing a semiconductor device, comprising forming a silicon oxide-containing layer on a semiconductor substrate; forming a photoresist pattern on the silicon oxide-containing layer; and then etching the silicon oxide-containing layer the photoresist pattern as an etch mask by plasma etching, using a linear octafluorobutene as an etching gas.

In specific embodiments, the silicon oxide-containing layer is formed of SiO₂, borophosphosilicate glass (BPSG), phosphosilicate glass (PSG), or silicon oxynitride (SiOₓN_{y}).

According to other specific embodiments, before forming the silicon oxide-containing layer, the semiconductor device manufacturing method further includes forming a plurality of conductive patterns on the semiconductor substrate, and forming a first insulation layer with a different material from the silicon oxide-containing layer, such that at least a portion of the conductive patterns is covered with the first insulation layer. In such embodiments, the silicon oxide-containing layer is formed over the first insulation layer. In etching the silicon oxide-containing layer, the first insulation layer is used as an etch barrier.

In accordance with still another aspect of the present invention, there is provided a method for manufacturing a semiconductor device that includes forming an insulation layer on a semiconductor substrate, and then etching the insulation layer by plasma using an etching gas containing a linear octafluorobutene.

Semiconductor devices manufactured according to the inventive methods are also provided.

### BRIEF DESCRIPTION OF THE DRAWINGS

The above features and advantages of the present invention will become more apparent by describing in detail specific embodiments thereof with reference to the attached drawings in which:

FIG. 1 is a flowchart illustrating an embodiment of a method for manufacturing a semiconductor device according to the present invention; and

FIGS. 2A and 2B are sectional views illustrating a method for forming a self-aligned contact hole on a semiconductor substrate using the semiconductor device manufacturing method according to the present invention.

### DETAILED DESCRIPTION OF THE INVENTION

The priority Korean Patent Application No. 00-50358, filed Aug. 29, 2000, is hereby incorporated in its entirety by reference.

According to the present invention, the oxide layer can be etched at a faster etch rate by plasma etching, thereby improving throughput. In addition, the excellent oxide-to-nitride etching selectivity is advantageous in forming a contact hole or self-aligned contact hole with a high aspect ratio for highly integrated semiconductor devices.

The present invention will now be described more fully with reference to the accompanying drawings, in which specific embodiments of the invention are shown. This invention may, however, be embodied in many different forms and should not be construed as being limited to the embodiments set forth herein. Rather, these embodiments are provided so that this disclosure will be thorough and complete, and will fully convey the concept of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers can also be present.

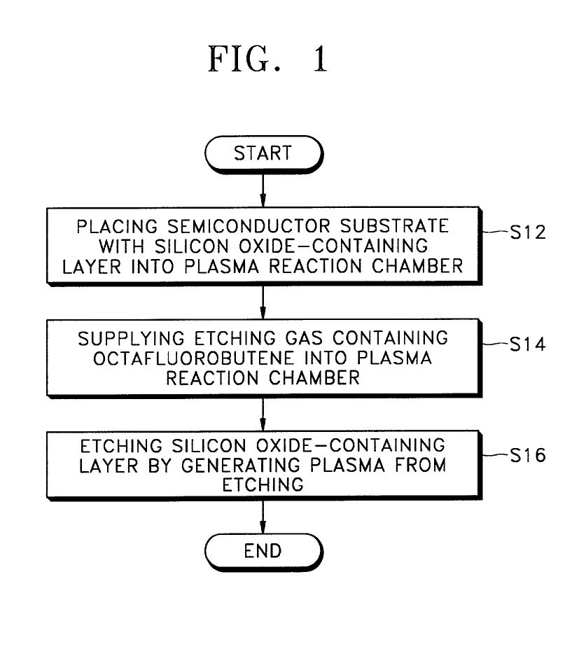

A particular embodiment of a method for manufacturing a semiconductor device according to the present invention will be described with reference to FIG. 1. Referring to FIG. 1, in step 12, a semiconductor substrate with a silicon oxide-containing layer thereon is placed into a plasma reaction chamber. The silicon oxide-containing layer can be formed of, for example, SiO₂, borophosphosilicate glass (BPSG), phosphosilicate glass (PSG), or silicon oxynitride (SiOₓN_{y}). A silicon nitride layer as an etch barrier may be interposed between the silicon oxide-containing layer and the semiconductor substrate.

As a plasma etching apparatus having the plasma reaction chamber, a variety of common plasma etching apparatuses including a high-density plasma etching apparatus such as inductively coupled plasma (ICP) or electron-cyclotron resonance (ECR) can be used.

In step 14, an etching gas containing the linear unsaturated compound octafluorobutene (hereinafter, simply referred to as “/-C₄F₈”), is supplied into the plasma reaction chamber. /-C4F8 can be octafluoro-1-butene (CF₂=CFCF₂CF₃) or octafluoro-2-butene (CF₃CF—CFCF₃).

Unlike octafluorocyclobutane (c-C₄F₈), a widely used conventional etching gas, /-C₄F₈ (octafluoro-1-butene or octafluoro-2-butene) has a linear molecular structure with an unsaturated double bond. Due to this double bond, /-C₄F₈ is liable to decompose in a plasma atmosphere and is highly reactive. During dry plasma etching, /-C₄F₈ produces more reactive radicals than c-C₄F₈ does, with improved dry etching characteristics. The lifetime of /-C₄F₈ in the air is very short, and its global warming potential (GWP) is small at less than 100. Accordingly, use of /-C₄F₈ is desirable in terms of environmental concerns.

The etching gas can further include a CₓF_{y}-based gas, where x=1-5, and y=2-12; a CₓH_{y}F_{z}-based gas, where x=1,−5, y=1-4, and z=2-10; or a mixture of these gases. For example, suitable CₓF_{y}-based gases include CF₄, C₂F₆, C₃F₆, C₃F₈, C₄F₆, c-C₄F₈, and C₅F₈. Suitable CₓH_{y}F_{z},-based gases include CHF₃, CH₂F₂, and CH₃F.

Alternatively, the etching gas can include a rare (i.e., noble) gas such as argon (Ar). Suitable rare gases include helium (He), krypton (Kr), and Xenon (Xe), other than Ar. The etching gas can also include O₂. For example, if a gas mixture of /-C₄F₈, Ar and O₂ is used as an etching gas, the /-C₄F₈-to-O₂ flow rate ratio beneficially is in the range from about 1:1 to about 3:1.

Then, in step 16, plasma is generated from the etching gas, and the silicon oxide-containing layer is etched by the plasma. In this step, the silicon oxide-containing layer can be etched to form a trench in a damascene process, or a contact hole or self-aligned contact hole through the silicon oxide-containing layer in another process, i.e., depending on the particular process of the semiconductor device manufacture.

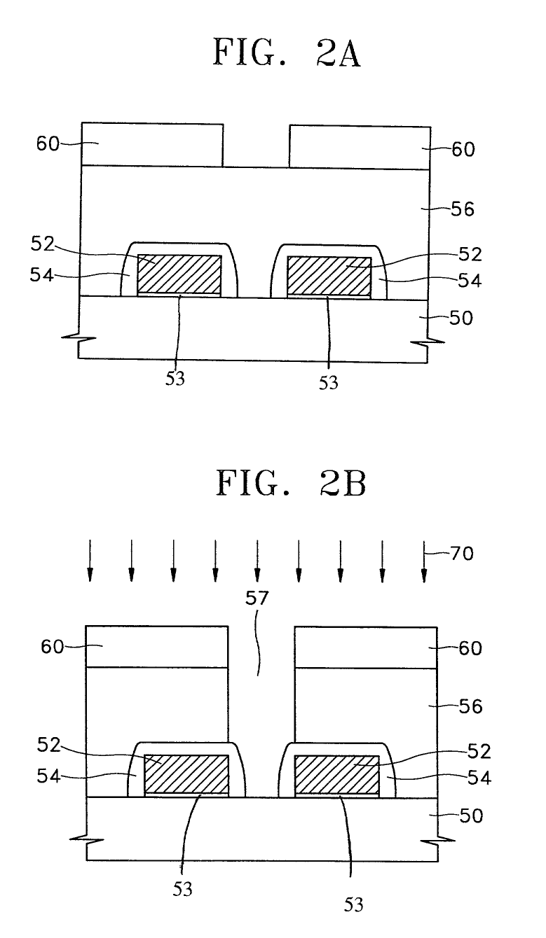

FIGS. 2A and 2B are sectional views illustrating formation of a self-aligned contact hole 57 on a semiconductor substrate 50 using the etching gas in the manufacture of a semiconductor device. Referring to FIG. 2A, a plurality of conductive patterns 52, for example, gate electrode patterns, whose top surface and sidewalls are covered by a silicon nitride layer 54, are formed on the semiconductor substrate 50 (and intervening gate oxide film 53). Next, a silicon oxide-containing layer 56 is deposited to cover the silicon nitride layer 54. The silicon oxide-containing layer 56 can be formed with a material described previously. Then, a photoresist pattern 60, through which a predetermined region of the silicon oxide-containing layer 56 is exposed, is formed on the silicon oxide-containing layer 56.

Referring to FIG. 2B, the exposed portion of the silicon oxide-containing layer 56 is etched using the photoresist pattern 60 as an etch mask, by dry etching using plasma 70, thereby resulting in the contact hole 57 self-aligned with the conductive pattern 52. Here, the plasma 70 is generated from an etching gas containing /-C₄F₈ as a linear unsaturated compound.

The plasma 70 generated from /-C₄F8 contained in the etching gas has a high oxide-to-nitride etching selectivity, and a faster etch rate over the oxide layer than other CₓF_{y}-based etching gases extensively used in conventional etching processes. Accordingly, even in forming a contact hole with high aspect ratio for a highly integrated semiconductor device, the contact hole 57 having a desired shape can be formed by the plasma 70 without consuming the silicon nitride layer 54 used as an etch barrier.

As described previously, the etching gas used in generating the plasma 70 can further include a CₓF_{y}-based gas, where x=1-5, and y=2-12; a CₓH_{y}F_{z}-based gas, where x=1,−5, y=1-4, and z=2-10; or a mixture of these gases. The etching gas can further include a rare gas such as Ar, and also O₂. For example, as the etching gas, a gas mixture of /-C₄F₈ at 18 sccm, Ar at 700 sccm, and O₂ at 8 sccm can be supplied. In this case, He, Kr or Xe can be used instead of Ar.

Table 1 comparatively shows properties of /-C₄F₈ used in the manufacture of a semiconductor device according to the present invention, and of c-C₄F₈ as a widely used conventional etching gas.

TABLE 1

| | Boiling point | | Lifetime | |
|---|---|---|---|---|
| Kind of gas | (EC) | GWP | (hr) | Flammability |
| c-C₄F₈ | !5.7 | 9100 | 3200 | No |
| (octafluorocy- | | | | |
| clobutane) | | | | |
| I-C₄F₈ | 1.3 | <100 | <1 | No |
| (octafluoro-2- | | | | |
| butene) | | | | |

As shown in Table 1, the lifetime of /-C₄F₈ in the air is very short, and its GWP is also small at less than 100, so that use of /-C₄F₈ is benefit in terms of environmental concerns.

Etching characteristics of /-C₄F₈ used in the manufacture of a semiconductor device according to the present invention, and of c-C₄F₈ as a widely used conventional etching gas, were evaluated as follows. A silicon dioxide layer deposited over a semiconductor substrate was etched to form a contact hole or a self-aligned contact hole under the conventional recipe using a capacitively coupled plasma reactor with dual frequency. Gas mixtures of /-C₄F₈/O₂/Ar, and c-C₄F₈/O₂/Ar were used as etching gases to evaluate the etching characteristics of /-C₄F₈ and c-C₄F₈, respectively.

The conditions of the plasma reaction chamber within the etching apparatus were varied according to the type of contact hole to be formed. According to a general contact hole recipe, a contact hole was formed at a 25 mTorr chamber pressure with application of a 1600 W upper electrode RF power, and an 1800 W lower electrode RF power. In this case, when /-C₄F₈ (octafluoro-2-butene) was used as an etching gas, the flow rates of the gas mixture supplied into the plasma reaction chamber were controlled at 18 sccm for /-C₄F₈, at 10 sccm for O₂, and at 500 sccm for Ar. When c-C₄F₈ was used as an etching gas, the flow rates of the gas mixture were controlled at 18 sccm for c-C₄F₈, at 8 sccm for O₂, and at 500 sccm for Ar.

For a self-aligned contact hole recipe, the conditions of the plasma reaction chamber were controlled under a 30 mTorr chamber pressure, and a 1400 W RF power and a 1600 W RF power were applied to upper and lower electrodes, respectively. In this case, when /-C₄F₈ was used as an etching gas, the flow rates of the gas mixture supplied into the plasma reaction chamber were controlled at 18 sccm for /-C₄F₈, at 8 sccm for O₂, and at 700 sccm for Ar. When c-C₄F₈ was used as an etching gas, the flow rates of the gas mixture were controlled at 18 sccm for c-C₄F₈, at 7 sccm for O₂, and at 700 sccm for Ar. The results of the evaluation are shown in Table 2.

TABLE 2

| | | Etch rate²⁾ (Δ/min) | |
|---|---|---|---|
| | Gas decomposition | Contact hole | Self-aligned contact |
| Kind of gas | ratio¹⁾ (%) | recipe | hole recipe |
| c-C₄F₈ | about 84 | −5,000 | −3,620 |
| (octafluorocy- | | | |
| clobutane) | | | |
| I-C₄F₈ | >94 | −5,250 | −4,090 |
| (octafluoro-2- | | | |
| butene) | | | |

¹⁾The gas decomposition ratio was measured using quadrupole mass spectrometry (QMS) based on the intensity of C₃F₅⁺ ions detected before and after etching.
²⁾The etch rate was obtained through a conventional etching recipe for a silicon dioxide layer.

As shown in Table 2, about 84% of c-C₄F₈ decomposes in the plasma reaction chamber, whereas more than 94% of octafluoro-2-butene selected as an /-C₄F₈ decomposes. The etch rate of octafluoro-2-butene is faster than that of c-C₄F₈ for both a contact hole and self-aligned contact hole. As a result of observation with a scanning electron microscope (SEM), both the contact hole and the self-aligned contact hole formed using octafluoro-2-butene have almost the same excellent profile. From these results, an improvement in throughput can be expected when octafluoro-2-butene as an /-C₄F₈ gas is used for etching an oxide layer.

To evaluate an oxide-to-nitride etching selectivity for both c-C₄F₈ and octafluoro-2-butene as an /-C₄F₈ gas, a contact hole self-aligned with conductive patterns for a semiconductor device having a 170-nm design rule was formed in the oxide layer using each of the gas mixtures, and then the thickness of the remainder of the silicon nitride layer covering the underlying conductive patterns was measured at the upper corners of the conductive patterns. The same plasma etching conditions as for the results of Table 2 were applied, except that the oxide layer was 100% over etched to form a self-aligned contact hole having a 0.23 μm width and a 0.5 μm depth. As a result, the silicon nitride layer remains at the corners of conductive patterns 144 Δ thick for c-C₄F₈, and 396 Δ thick for octafluoro-2-butene selected as an /-C₄F₈ gas. In other words, the thickness of the silicon nitride layer remaining after etching the oxide layer into a self-aligned contact hole is larger when octafluoro-2-butene selected as an /-C₄F₈ gas is used as the etching gas, compared with the case where a widely used c-C₄F₈ gas is used. The oxide-to-nitride etching selectivity is better for octafluoro-2-butene than for c-C₄F₈.

As described previously, in the method for manufacturing a semiconductor device according to the present invention, when an oxide layer is etched by plasma etching into a contact hole or self-aligned contact hole for highly integrated semiconductor devices, octafluorobutene (/-C₄F₈) having a linear molecular structure with an unsaturated double bond is used as an etch gas. Due to this double bond, /-C₄F₈ is liable to decompose in a plasma atmosphere, and is able to generate a large number of reactive radicals with better etching characteristics than other widely known conventional etching gases. The lifetime of /-C₄F₈ in the air is very short, and its GWP is small at less than 100. Accordingly, use of /-C₄F₈ is desirable in terms of environmental concerns.

In addition, when /-C₄F₈ is used as an etching gas during a plasma etching process in the manufacture of a semiconductor device, due to its faster etch rate than other conventional etching gases, throughput can be improved. Excellent oxide-to-nitride etching selectivity of /-C₄F₈ is beneficial in forming a contact hole or a self-aligned contact hole with a large aspect ratio for highly integrated semiconductor devices.

While this invention has been particularly shown and described with reference to specific embodiments thereof, it will be understood by those skilled in the art that various changes in form and details may be made to the described embodiments without departing from the spirit and scope of the invention as defined by the appended claims.

What is claimed is:

1. A method for manufacturing a semiconductor device, comprising the steps of:
(i) placing a semiconductor substrate with a silicon oxide-containing layer thereon into a plasma reaction chamber;
(ii) supplying an etching gas containing a linear octafluorobutene into the plasma reaction chamber; and
(iii) etching at least a portion of the silicon oxide-containing layer by generating plasma from the etching gas.

2. The method of claim 1, wherein the octafluorobutene is octafluoro-1-butene (CF₂=CFCF₂CF₃) or octafluoro-2-butene (CF₃CF=CFCF₃).

3. The method of claim 1, wherein the etching gas further comprises at least one selected from the group consisting of a first gas having the formula CₓF_{y}, wherein x=1-5, and y=2-12, a second gas having the formula CₓH_{y}F_{z}, wherein x=1-5, y=1-4, and z=2-10, and a mixture thereof.

4. The method of claim 3, wherein the first gas is selected from the group consisting of CF₄, C₂F₆, C₃F₆, C₃F₈, C₄F₆, c-C₄F₈ (octafluorocyclobutane), and C₅F₈.

5. The method of claim 3, wherein the second gas is selected from the group consisting of CHF₃, CH₂F₂, and CH₃F.

6. The method of claim 1, wherein the etching gas further comprises a rare gas.

7. The method of claim 6, wherein the rare gas is selected from the group consisting of argon (Ar), helium (He), krypton (Kr) and xenon (Xe).

8. The method of claim 1, wherein the etching gas further comprises a rare gas and O₂.

9. The method of claim 8, wherein the octafluorobutene and O₂ are supplied at flowrates such that the ratio thereof is between about 1:1 and about 3:1.

10. The method of claim 1, wherein the silicon oxide-containing layer is formed of SiO₂, borophosphosilicate glass (BPSG), phosphosilicate glass (PSG), or silicon oxynitride (SiOₓN_{y}).

11. A method for manufacturing a semiconductor device, comprising the steps of:
(i) forming a silicon oxide-containing layer on a semiconductor substrate;
(ii) forming a photoresist pattern on the silicon oxide-containing layer; and
(iii) etching the silicon oxide-containing layer using the photoresist pattern as an etch mask by plasma etching, using a linear octafluorobutene as an etching gas.

12. The method of claim 11, wherein the silicon oxide-containing layer is formed of SiO₂, borophosphosilicate glass (BPSG), phosphosilicate glass (PSG), or silicon oxynitride (SiOₓN_{y}).

13. The method of claim 11, wherein, in etching the silicon oxide-containing layer in step (iii), a contact hole passing through the silicon oxide-containing layer is formed.

14. The method of claim 11, further comprising, before step (i), the steps of forming a plurality of conductive patterns on the semiconductor substrate, and forming a first insulation layer with a different material from the silicon oxide-containing layer, such that at least a portion of the conductive patterns is covered with the first insulation layer, wherein the silicon oxide-containing layer is formed over the first insulation layer.

15. The method of claim 14, wherein, in step (iii), the first insulation layer is used as an etch barrier.

16. The method of claim 15, wherein, in step (iii), a contact hole self-aligned with the conductive patterns and passing through the silicon oxide-containing layer is formed.

17. The method of claim 14, wherein the first insulation layer is a silicon nitride layer.

18. The method of claim 11, wherein the octafluorobutene is octafluoro-1-butene (CF₂=CFCF₂CF₃) or octafluoro-2-butene (CF₃CF=CFCF₃).

19. The method of claim 18, wherein the etching gas further comprises at least one selected from the group consisting of a first gas having the formula CₓF_{y}, wherein x=1-5, and y=2-12, a second gas having the formula CₓH_{y}F_{z}, wherein x=1-5, y=1-4, and z=2-10, and a mixture thereof.

20. The method of claim 18, wherein the etching gas further comprises a rare gas.

21. The method of claim 18, wherein the etching gas further comprises a rare gas and O₂.

22. The method of claim 21, wherein the octafluorobutene and O₂ are supplied at flowrates such that the ratio thereof is between about 1:1 and about 3:1.

23. A method for manufacturing a semiconductor device, comprising:
forming an insulation layer on a semiconductor substrate; and
etching the insulation layer by plasma etching using an etching gas containing a linear octafluorobutene.

24. A semiconductor device produced according to the method of claim 1.

25. A semiconductor device produced according to the method of claim 11.

26. A semiconductor device produced according to the method of claim 23.
